(19) United States
(12) Patent Application Publication
(10) Pub. No.: US 2026/0206357 A1
(43) Pub. Date: Jul. 16, 2026

(54) STRING REPAIR DEVICE AND STRING REPAIR METHOD

(71) Applicant: HANWHA SOLUTIONS CORPORATION, Seoul (KR)

(72) Inventors: Han Jin LEE, Seoul (KR); Nam Gon KIM, Seoul (KR); Hyun Jae RYU, Seoul (KR)

(73) Assignee: HANWHA SOLUTIONS CORPORATION, Seoul (KR)

(21) Appl. No.: 19/129,902

(22) PCT Filed: May 3, 2024
(86) PCT No.: PCT/KR2024/006054

§ 371 Date: May 14, 2025

(30) Foreign Application Priority Data
May 16, 2023 (KR) 10-2023-0063282

(51) Int. Cl. H10F 71/00; H10F 19/90; H10F 77/00

(52) U.S. Cl. CPC H10F 71/1375; H10F 19/902; H10F 77/939

(57) ABSTRACT

A string repair device includes: a stage supporting a string including a plurality of solar cells and a plurality of wires connecting the plurality of solar cells; and an aligning device configured to, after a defective solar cell of the string is replaced with a new solar cell, align a plurality of wires attached to the new solar cell and a plurality of wires of two solar cells adjacent to the new solar cell, wherein the plurality of solar cells include a plurality of printing areas to which the plurality of wires are each attached, and the aligning device maintains each of the plurality of wires attached to the new solar cell and the plurality of wires of the two solar cells adjacent to the new solar cell in the plurality of printing areas.

### TECHNICAL FIELD

The present disclosure relates to a string repair device and a string repair method.

### BACKGROUND ART

Solar cells, i.e., solar batteries, are formed by arranging diodes having p-n junctions on substrates. When solar cells are irradiated with solar radiation, excitons, which are electron-hole pairs, are generated, electrons move to the n-layer and holes move to the p-layer as the excitons are separated, and accordingly, a photoelectromotive force is generated at p-n junctions.

Tabbing is a process of forming a string, which is a single module of solar cells, by electrically connecting a plurality of solar cells using wires. A string extends in a straight line with a plurality of wires alternately arranged on front surfaces and rear surfaces of a plurality of solar cells. Wires arranged on a front surface of a single solar cell are alternately arranged by being arranged on a rear surface of an adjacent solar cell and then being arranged on a front surface of a subsequent solar cell.

However, conventionally, when some solar cells included in a string are defective, damaged, or not properly bonded to wires, there has been an inconvenience in that a person should directly remove the corresponding solar cells from the string and replace them with new solar cells.

In order to address such an inconvenience, an automated repair device has been developed, but it is not possible to properly align wires in a process in which a wire connected to a defective solar cell of a string is cut and then a wire attached to a new solar cell is connected to the remaining wires of the string. As a result, since the new solar cell is not able to be properly bonded to the wires of the string, there are problems in that the repair task takes a long time, and the quality of the string decreases.

### DISCLOSURE

### Technical Problem

Embodiments of the present disclosure are directed to providing a string repair device and a string repair method capable of automating a string repair process and easily aligning wires of a string and a wire of a new solar cell during the repair process.

### Technical Solution

A string repair device includes: a stage supporting a string including a plurality of solar cells and a plurality of wires connecting the plurality of solar cells; and an aligning device configured to, after a defective solar cell of the string is replaced with a new solar cell, align a plurality of wires attached to the new solar cell and a plurality of wires of two solar cells adjacent to the new solar cell, wherein the plurality of solar cells include a plurality of printing areas to which the plurality of wires are each attached, and the aligning device aligns the plurality of wires attached to the new solar cell and the plurality of wires of the two solar cells adjacent to the new solar cell in the plurality of printing areas.

The plurality of printing areas may form a plurality of rows in a longitudinal direction, and the aligning device may align a plurality of wires of a solar cell adjacent to a front of the new solar cell so that the plurality of wires are located in a first printing area row of the new solar cell and may align the plurality of wires attached to the new solar cell so that the plurality of wires are located in a first printing area row of a solar cell adjacent to a rear of the new solar cell.

The aligning device may primarily move downward to a position spaced a predetermined height from an upper surface of the solar cell to align the plurality of wires downward, may secondarily move downward so that a lower end comes into contact with the upper surface of the solar cell, and then may align the plurality of wires in a width direction.

The plurality of printing areas may form a plurality of rows in a longitudinal direction, and the aligning device may primarily move downward from a first position corresponding to a first printing area row, may secondarily move downward from a second position reached by moving a predetermined distance rearward, may press the plurality of wires to the upper surface of the solar cell, and then may align the plurality of wires in a width direction.

The string repair device may further include a bonding device bonding the plurality of wires aligned by the aligning device to the solar cell, and the bonding device may be supported on the aligning device so that at least a portion overlaps the aligning device in a state in which the aligning device is secondarily moved downward.

The aligning device may include a first aligning plate including a plurality of first aligning protrusions and a second aligning plate including a plurality of aligning grooves and a plurality of second aligning protrusions arranged alternately with the plurality of first aligning protrusions, and the aligning device may move at least one of the first aligning plate and the second aligning plate to align the plurality of wires, which are inserted into the plurality of aligning grooves, in a width direction.

A depth of the plurality of aligning grooves may be smaller than a diameter of the wires, and a width of the plurality of aligning grooves may be greater than a width of the printing areas.

A string repair method includes placing a string including a plurality of solar cells and a plurality of wires connecting the plurality of solar cells on a stage, cutting a plurality of wires connected between a defective solar cell and two solar cells adjacent to the defective solar cell among the plurality of solar cells, replacing the defective solar cell with a new solar cell, and aligning a plurality of wires attached to the new solar cell and a plurality of wires of the solar cells adjacent to the new solar cell, wherein the plurality of solar cells include a plurality of printing areas to which the plurality of wires are attached, and the aligning of the plurality of wires includes aligning the plurality of wires attached to the new solar cell and the plurality of wires of the two solar cells adjacent to the new solar cell in the plurality of printing areas.

The plurality of printing areas may form a plurality of rows in a longitudinal direction, and the aligning of the plurality of wires may include aligning the plurality of wires downward from a position corresponding to a first printing area row of the solar cell, pressing the plurality of wires to an upper surface of the solar cell from a position spaced rearward from the position corresponding to the first printing area row, and aligning the plurality of wires in the first printing area row by pressing the plurality of wires in a width direction.

The aligning of the plurality of wires may include, after performing a series of aligning steps for a plurality of wires of the new solar cell, performing the series of aligning steps for a plurality of wires of a solar cell adjacent to a rear of the new solar cell.

### Advantageous Effects

A string repair device and a string repair method according to embodiments of the present disclosure allow a repair process to be smoothly performed by aligning wires using an aligning device in an automatic string repair process.

A string repair device and a string repair method according to embodiments of the present disclosure can stably support and align wires through a downward moving operation of an aligning device.

In a string repair device and a string repair method according to embodiments of the present disclosure, by an aligning device overlapping a bonding device, the bonding device can stably bond a wire.

### DESCRIPTION OF DRAWINGS

FIG. 1 schematically illustrates a string manufacturing system including a string repair device.

FIGS. 2A to 2J illustrate operations of the string repair device.

FIGS. 3 to 5 illustrate some of the operations of the string repair device.

FIG. 6 illustrates an aligning device.

FIG. 7 illustrates a bottom surface of the aligning device.

FIG. 8 illustrates a cross-section of the aligning device.

FIGS. 9 to 15 illustrate aligning operations of the aligning device.

FIG. 16 illustrates the aligning device and a bonding device.

### BEST MODE OF THE INVENTION

A string repair device includes: a stage supporting a string including a plurality of solar cells and a plurality of wires connecting the plurality of solar cells; and an aligning device configured to, after a defective solar cell of the string is replaced with a new solar cell, align a plurality of wires attached to the new solar cell and a plurality of wires of two solar cells adjacent to the new solar cell, wherein the plurality of solar cells include a plurality of printing areas to which the plurality of wires are attached, and the aligning device aligns the plurality of wires attached to the new solar cell and the plurality of wires of the two solar cells adjacent to the new solar cell in the plurality of printing areas.

### Modes of the Invention

Embodiments of the present disclosure and methods of accomplishing the same may be understood more readily with reference to the detailed description of the embodiments and the accompanying drawings. Hereinafter, the embodiments will be described in more detail with reference to the accompanying drawings. The described embodiments, however, may have various modifications and may be embodied in various different forms, and should not be construed as being limited to only the illustrated embodiments herein. In addition, different features of various embodiments of the present disclosure may be combined, may be combined with each other partially or entirely, or may be technically linked and driven in various ways. Different embodiments may be embodied independently from each other or may be embodied together in association with each other. The embodiments described herein are provided as examples to make the present disclosure thorough and complete and to fully convey the idea of the present disclosure to those of ordinary skill in the art, and it should be understood that the present disclosure covers all modifications, equivalents, and replacements within the idea and technical scope of the present disclosure. Accordingly, processes, components, and techniques that are not necessary to those of ordinary skill in the art for a complete understanding of the aspects of the present disclosure may not be described.

Unless otherwise noted, like reference numerals, characters, or combinations thereof denote like components throughout the attached drawings and the written description, and thus descriptions thereof will not be repeated. Further, parts that are irrelevant to the description of the embodiments may be omitted to make the description clear.

In the drawings, the relative sizes of components, layers, and regions may be exaggerated for clarity. Additionally, the use of cross-hatching and/or shading in the accompanying drawings is generally provided to clarify boundaries between adjacent components. As such, neither the presence nor the absence of cross-hatching or shading conveys or indicates any preference or requirement for particular materials, material properties, dimensions, proportions, commonalities between illustrated components, and/or any other characteristic, attribute, property, etc., of the components, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

The regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the specification, numerous specific details are set forth to provide a thorough understanding of various embodiments. However, various embodiments may be practiced without these specific details or with one or more of the details. In other instances, well-known structures and devices are shown in block diagram form in order to avoid unnecessarily obscuring various embodiments.

Spatially relative terms, such as “beneath,” “above,” “below,” and “on,” may be used herein for ease of explanation to describe one component or feature's relationship to another component(s) or feature(s) as illustrated in the figures. The spatially relative terms are intended to encompass different orientations of the device in use or in operation, in addition to the orientation depicted in the figures. For example, if the device in the figures is turned over, components described as “below” or “beneath” other components or features would then be oriented “above” the other components or features. Thus, the example terms “below” and “beneath” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part.

In addition, the phrase “in a plan view” means viewing an object from the top, and the phrase “in a schematic cross-sectional view” means viewing a schematic cross-section formed by vertically cutting an object. The phrase “viewed from a side” means that a first object may be present above, below, or beside a second object, and vice versa. In addition, the term “overlap” or “overlapped” may include layer, stack, face or facing, extending over, covering, or partly covering or any other suitable term as would be appreciated and understood by those of ordinary skill in the art. The phrase “not overlap” may include meanings such as “being apart from” or “being spaced from” or any other suitable equivalents as would be appreciated and understood by those of ordinary skill in the art. The terms “face” and “facing” may mean that a first object may directly or indirectly oppose a second object. In the case where a third object is present between the first object and the second object, the first object and the second object may be understood as being indirectly opposed to each other, although still facing each other.

When an element, layer, region, or component is referred to as being “formed on,” “connected to,” or “coupled to” another element, layer, region, or component, the other element, layer, region, or component may be directly formed on the element, layer, region, or component, or the element, layer, region, or component may be formed on the other element, layer, region, or component or may be indirectly formed on, connected to, or coupled to the other element, layer, region, or component. In addition, “formed on,” “connected to,” or “coupled to” may collectively mean a direct or indirect coupling or connection and an integral or non-integral coupling or connection of elements, layers, regions, or components for one or more elements, layers, regions, or components to be present. For example, when an element, layer, region, or component is referred to as being “electrically connected” or “electrically coupled” to another element, layer, region, or component, the element, layer, region, or component can be directly electrically connected or coupled to the other element, layer, region, or component or other elements, layers, regions, or components may be present. However, “directly connected” or “directly coupled” refers to one component directly connecting or coupling another component, or being on another component, without an intermediate component. In addition, if a portion of a layer, film, region, guide plate, or the like is formed on another portion, a formation direction is not limited to an upper direction, and the portion may be formed on a side surface of or under the other portion. In contrast, if a portion of a layer, film, region, guide plate, or the like is formed “under” another portion, the portion may be “just underneath” the other portion, or an intervening portion may be present between the portion and the other portion. Meanwhile, other expressions describing relationships between components such as “between,” “immediately between” or “adjacent to” and “directly adjacent to” may be construed similarly. In addition, if an element or layer is referred to as being “between” two elements or layers, this may be the only element between the two elements or layers, or another element may be present therebetween.

For the purposes of this specification, the expressions such as “at least one” or “any one” do not limit the order of individual elements. For example, “at least one of X, Y, and Z,” “at least one of X, Y, or Z,” and “at least one selected from the group consisting of X, Y, and Z” may include any combination of two or more of X alone, Y alone, Z alone, and two or more of X, Y, and Z. Similarly, the expressions such as “at least one of A and B” and “at least one of A or B” may include A, B, or A and B. In this specification, the term “and/or” generally includes all combinations of one or more related list items. For example, expressions such as “A and/or B” may include A, B, or A and B.

The terms “first,” “second,” “third,” etc. may be used herein to describe various elements, components, regions, layers, and/or cross-sections, but these elements, components, regions, layers, and/or cross-sections are not limited by these terms. These terms are used to distinguish one element, component, region, layer, or cross-section from another element, component, region, layer, or cross-section. Therefore, a first element, component, region, layer, or cross-section described below may be referred to as a second element, component, region, layer, or cross-section without departing from the spirit and scope of the present invention. Describing an element as a “first” element may not require or imply the presence of a second element or another element. The terms “first,” “second,” etc. may be used herein to distinguish between different categories or sets of elements. In order to express clearly, the terms “first,” “second,” etc. may refer to a “first category (or a first set),” a “second category (or a second set)” and the like, respectively.

The terms used herein are used only to describe particular embodiments and are not intended to limit the present invention. As used herein, a singular expression is intended to include a plural expression, and the plural expression is also intended to include a singular form unless the context clearly indicates otherwise. The terms “comprise,” “include,” and “have” mean specifying the presence of specified features, integers, and steps if used herein. These expressions do not preclude the presence or addition of one or more other functions, steps, operations, components, and/or groups thereof.

If one or more embodiments may be embodied differently, a particular process order may be performed differently from the order described. For example, two processes described in succession may be performed substantially simultaneously or in the opposite order to the order described.

The terms “substantially,” “about,” “approximately,” and similar terms are used not as terms of degree but as terms of approximation and indicate that the terms satisfy the range of intrinsic deviations of measured or calculated values (e.g., the range of deviations due to limitations of a measurement system). For example, “about” may mean within one or more standard deviations or within +30%, 20%, 10%, and 5% of stated values.

Unless otherwise defined, all terms used herein, including technical or scientific terms, have the same meaning as those generally understood by one of ordinary skill in the art to which the present invention belongs. Terms, such as those defined in commonly used dictionaries, should be interpreted as having a meaning that is consistent with their meaning in the context of the relevant art and/or the present specification and will not be interpreted in an idealized or overly formal sense unless expressly so defined herein.

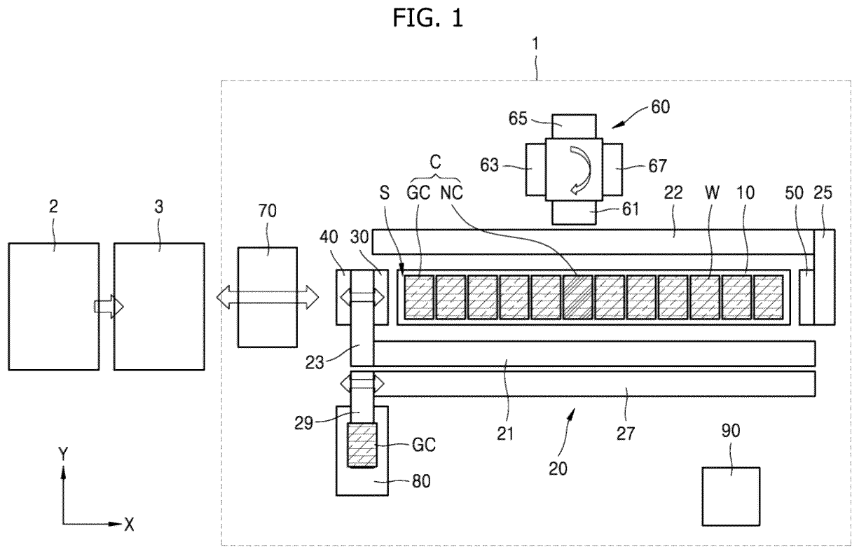

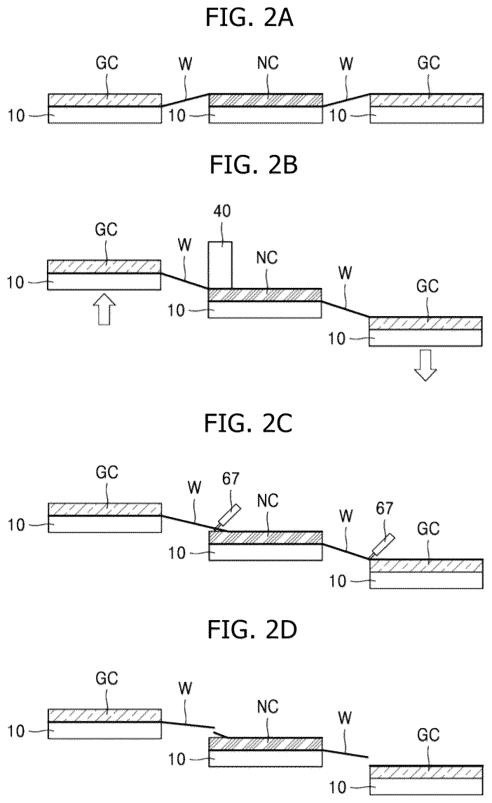

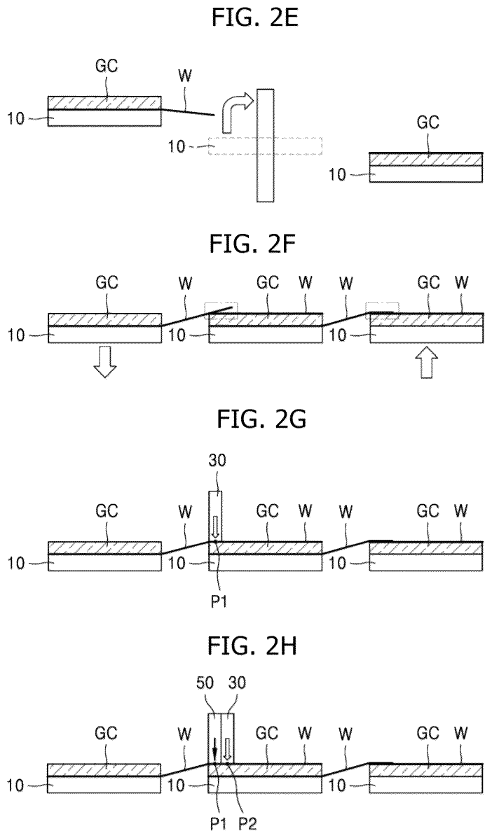

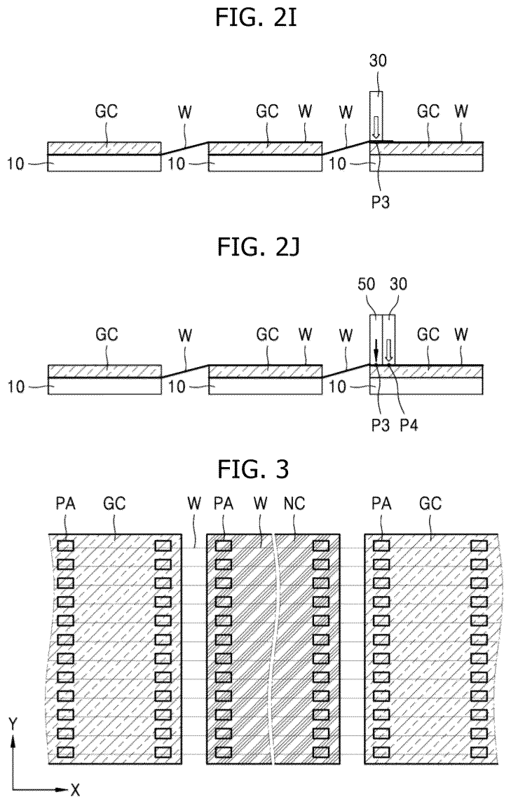

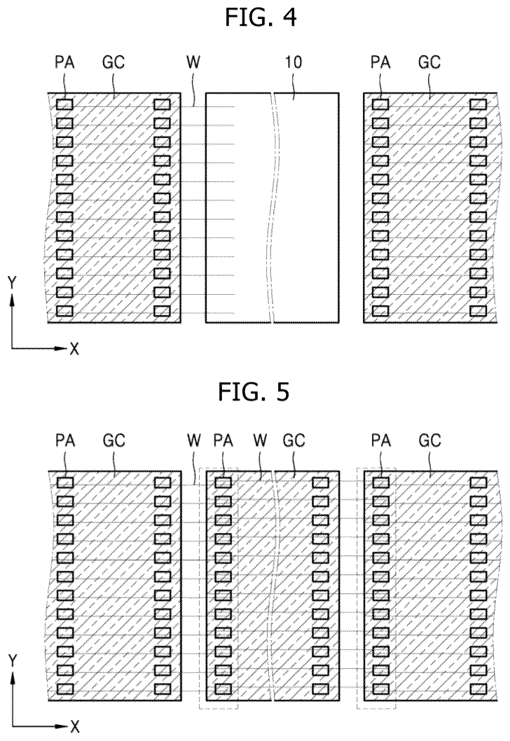

FIG. 1 schematically illustrates a string manufacturing system including a string repair device 1, FIG. 2 illustrates operations of the string repair device 1, and FIGS. 3 to 5 illustrate some of the operations of the string repair device 1, wherein FIG. 3 illustrates a state before wires W of a defective solar cell NC are cut, FIG. 4 illustrates a state in which the defective solar cell NC is discharged, and FIG. 5 illustrates a state in which the defective solar cell NC is replaced with a good solar cell GC and then wires W are aligned in printing areas PA.

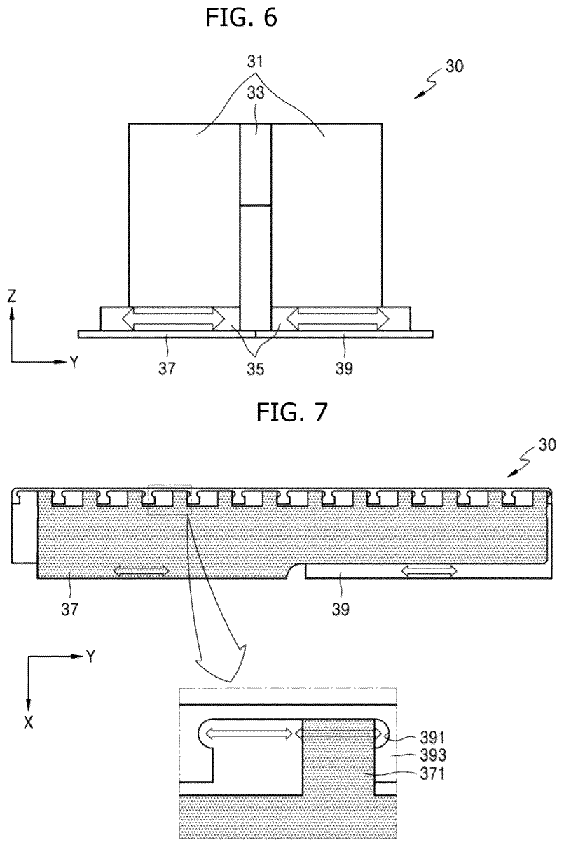

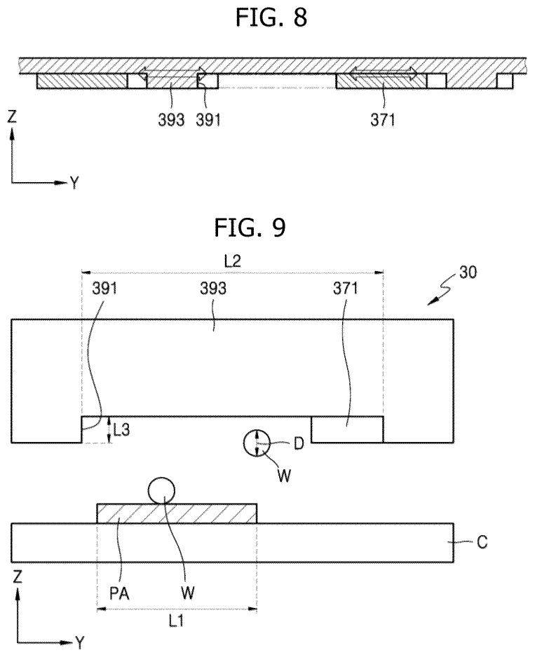

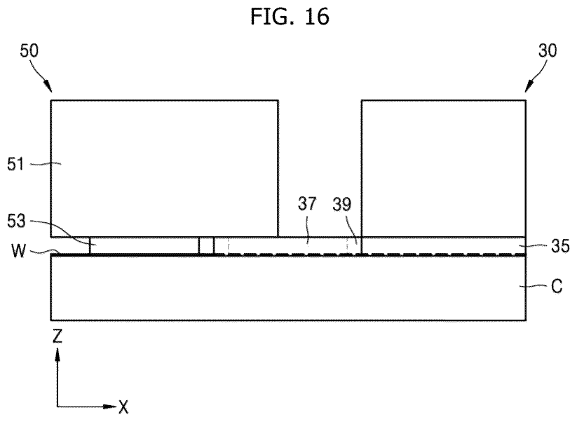

FIG. 6 illustrates an aligning device 30, FIG. 7 illustrates a bottom surface of the aligning device 30, FIG. 8 illustrates a cross-section of the aligning device 30, FIGS. 9 to 15 illustrate aligning operations of the aligning device 30, and FIG. 16 illustrates the aligning device 30 and a bonding device 50.

Referring to FIG. 1, the string repair device 1 may be included in the string manufacturing system together with a tabbing device 2 and an inspecting device 3. The tabbing device 2 may produce a string S by connecting solar cells C and wires W. The string S may include a plurality of solar cells C and a plurality of wires W connecting the plurality of solar cells C. The plurality of solar cells C may be arranged in a first direction (for example, the X-axis direction of FIG. 1 or a conveying direction of the solar cells C), and the plurality of wires W may be attached alternately to one surface and another surface of each solar cell C and electrically connect the plurality of solar cells C. As illustrated in FIG. 2A, a wire W attached to a lower surface of any one solar cell C may be attached to an upper surface of an adjacent solar cell C. Also, a wire W attached to an upper surface of any one solar cell C may be attached to a lower surface of an adjacent solar cell C. For convenience of description, FIGS. 2A to 2J illustrate that only one wire W is attached to solar cells C located at both sides of a solar cell C to be replaced, but the corresponding solar cells C may also have wires W additionally attached to an upper surface and a lower surface thereof as described above.

The number of solar cells C and wires W included in a single string S may be appropriately selected according to specifications of the string S. For example, twelve solar cells C may be arranged consecutively in a single string S, and six or twelve wires W may be attached to a single solar cell C in a width direction. Although six wires W are shown in FIG. 1 for convenience of description, twelve wires W may be attached to each of a plurality of solar cells C in the width direction as shown in FIGS. 3 to 5.

Each solar cell C may include a plurality of printing areas PA. The printing areas PA may be areas where a plurality of wires W are attached to a solar cell C. For example, as illustrated in FIG. 3, a plurality of printing areas PA may be formed on a single solar cell C in the longitudinal direction and width direction thereof. The printing areas PA may include a conductive material. The wires W may be electrically connected to the solar cell C through the printing areas PA. Each wire W may be attached to the plurality of printing areas PA arranged in the longitudinal direction of a single solar cell C. Also, a width of the printing area PA may be greater than a diameter of the wire W. Printing areas PA equal in number to the plurality of wires W may be formed on a single solar cell C in the width direction thereof. For example, the plurality of printing areas PA may form a plurality of rows in the longitudinal direction. Twelve printing areas PA may be arranged on a single solar cell C in the width direction thereof. Hereinafter, for convenience of description, “first printing area PA row” may refer to a row of printing areas PA located at the front in the longitudinal direction, e.g., located first on the left side of FIGS. 2A to 2I, among the plurality of rows of printing areas PA formed on a single solar cell C.

A printing area PA may be formed on an upper surface of a solar cell C and may have a predetermined height. Although the height of the printing area PA is somewhat exaggerated in FIGS. 9 to 15 for convenience of description, the height of the printing area PA may substantially be very small compared to the thickness of the solar cell C or the diameter of a wire W.

The inspecting device 3 may inspect the string S produced by the tabbing device 2 for defects or foreign substances. For example, the inspecting device 3 may capture overall images of a front surface and a rear surface of the string S using a vision camera and may inspect whether solar cells C are damaged, whether connection between wires W and the solar cells C is good, whether there are foreign substances on the solar cells C, etc. If inspection results are normal, the string S may be conveyed to a subsequent process without a separate repair process. If inspection results show that there is a defect, the string S may be conveyed to the string repair device 1. In addition, the inspecting device 3 may also inspect the repaired string S to check whether the repair was done properly.

The string repair device 1 may repair and replace a string S determined to be defective by the inspecting device 3. For example, the string repair device 1 may replace a solar cell C that is determined to be a defective solar cell NC by the inspecting device 3 among the plurality of solar cells C included in the string S with a good solar cell GC.

The string repair device 1 may include a stage 10, a movement guide 20, the aligning device 30, a separating device 40, the bonding device 50, a robot arm 60, a transporting device 70, a magazine 80, and a controller 90.

The stage 10 may be arranged side by side to the string repair device 1 in the first direction (for example, the X-axis direction of FIG. 1) and may support the string S. The stage 10 may include a mechanical device (a gripper or a clamping means) for supporting the string S or may support the string S by adsorption. When the string S is determined to be defective by the inspecting device 3, the transporting device 70 may place the string S on an upper surface of the stage 10.

The stage 10 may be divided into three parts. A defective solar cell NC to be replaced may be located on a stage 10 located at a central portion, and the remaining good solar cells GC may be located on the stages 10 remaining at both sides. Alternatively, if a defective solar cell NC included in a string S is a solar cell C located at the very front or very rear in the first direction, the defective solar cell NC may be seated on any one stage 10, the remaining good solar cell GC may be seated on another stage 10, and the remaining stage 10 may be unoccupied.

The stage 10 may move upward and downward in a height direction to adjust the height of the defective solar cell NC to match the heights of adjacent good solar cells GC. For example, as illustrated in FIG. 2A, the plurality of solar cells C included in the string S may be seated on the stage 10, and here, the three parts that the stage 10 includes may all be located at the same height. Then, as illustrated in FIG. 2B, the two stages 10 adjacent to the front and rear (e.g., the left side and right side of FIG. 2B) of the stage on which the defective solar cell NC is located may move upward and downward, and height differences may be formed between the defective solar cell NC and the two good solar cells GC adjacent thereto. In this way, the heights of the stages 10 may be adjusted to make it easy to cut the plurality of wires W connecting the defective solar cell NC and the good solar cells GC adjacent thereto. The heights of the stages 10 may be adjusted by the stages 10 themselves moving in the height direction or tilting.

The stages 10 may also be movable in the longitudinal direction of the stages (for example, the X-axis direction of FIG. 1). The stages 10 located at both sides of the stage 10 on which the defective solar cell NC is seated may move forward or backward in the longitudinal direction.

The stage 10 on which the defective solar cell NC is seated may be rotatable. For example, as illustrated in FIG. 2F, the stage 10 may rotate clockwise or counterclockwise to discharge the defective solar cell NC after the wires W are cut. Accordingly, the defective solar cell NC seated on the stage 10 may be discharged from the stage 10, the stage 10 may rotate back to its original position, and then a new good solar cell GC may be seated on the stage 10.

The movement guide 20 may move the aligning device 30, the separating device 40, and the bonding device 50 along designated paths according to each string repair process. In addition, after the defective solar cell NC is removed from the string S, the movement guide 20 may move a good solar cell GC loaded in the magazine 80 to the position where the defective solar cell NC was present.

The movement guide 20 may include a first horizontal guide 21, a second horizontal guide 22, a first moving head 23, a second moving head 25, a third horizontal guide 27, and a third moving head 29.

The first horizontal guide 21 may extend in the first direction (for example, the X-axis direction of FIG. 1) side by side with the stage 10 and may be spaced from the stage 10. The first moving head 23 may be connected to the first horizontal guide 21, and the first moving head 23 may, while moving along the first horizontal guide 21, perform a task on the string S placed on the stage 10.

The second horizontal guide 22 may be located on the opposite side of the first horizontal guide 21 based on the stage 10 and may be arranged side by side with the stage 10. The second moving head 25 may be connected to the second horizontal guide 22, and the second moving head 25 may, while moving along the second horizontal guide 22, perform a task on the string S placed on the stage 10.

The aligning device 30 and the separating device 40 may be connected to the first moving head 23. For example, as illustrated in FIG. 1, the aligning device 30 may be connected to one side of the first moving head 23, and the separating device 40 may be connected to the other side, which is the opposite side of the aligning device 30. Therefore, when the first moving head 23 moves, the aligning device 30 and the separating device 40 connected to the first moving head 23 may move together. The first moving head 23 may move so that the separating device 40 is located on a wire w to be separated of the defective solar cell NC in the string S. In addition, the first moving head 23 may move so that the aligning device 30 is located on a wire W cut by a cutter 67. In addition, the first moving head 23 may move in the height direction and may simultaneously or separately lift or lower the aligning device 30 and the separating device 40 mounted thereon.

Alternatively, the first moving head 23 may include a plurality of first moving heads 23, and the aligning device 30 and the separating device 40 may be connected to each first moving head 23. Alternatively, the first moving head 23 may include a plurality of first moving heads 23, and a single aligning device 30 or a single separating device 40 may be connected to each first moving head 23.

The second moving head 25 may be connected to the bonding device 50. The second moving head 25 may move to a wire W aligned by the aligning device 30 and may allow the bonding device 50 to be placed on the cut wire W and a wire W attached to a new good solar cell GC. In addition, the second moving head 25 may move in the height direction and may lift or lower the mounted bonding device 50. Alternatively, the second moving head 25 may include a plurality of second moving heads 25.

The third horizontal guide 27 may extend in the first direction side by side with the stage 10 and may be adjacent to the first horizontal guide 21. Alternatively, the third horizontal guide 27 may be connected to a side of the second horizontal guide 22. The third moving head 29 is connected to the third horizontal guide 27, and while moving along the third horizontal guide 27, the third moving head 29 supports the good solar cell GC loaded in the magazine 80 and moves the good solar cell GC to the position where the defective solar cell NC was present.

The aligning device 30 may, while moving along the movement guide 20, align the wires W of the string S placed on the stage 10. The aligning device 30 may, once the defective solar cell NC is discharged from the stage 10 and a good solar cell GC is placed on the stage 10, align wires W attached to the good solar cell GC and wires W attached to two other solar cells GC adjacent thereto.

The aligning device 30 may maintain a plurality of wires W attached to the new solar cell GC and a plurality of wires W of the two solar cells GC adjacent to the new solar cell GC in a plurality of printing areas PA. In addition, the aligning device 30 may support the wires W at a position adjacent to the bonding device 50 when the bonding device 50 bonds the wires W. The aligning device 30 may be connected to the first moving head 23 connected to the first horizontal guide 21.

The aligning device 30 may place the plurality of wires W connected to the solar cell GC adjacent to the new solar cell GC in a first printing area PA row. For example, the aligning device 30 may align the plurality of wires W of the solar cell GC adjacent to the new solar cell GC (for example, located at the front thereof based on FIG. 5) so that the plurality of wires W are placed in the first printing area PA row in the longitudinal direction of the new solar cell GC (for example, the first direction or the X-axis direction of FIG. 5). In addition, the aligning device 30 may align the plurality of wires W attached to the new solar cell GC so that the plurality of wires W are placed in the first printing area PA row of the solar cell GC adjacent to the other side of the new solar cell GC (for example, located at the rear thereof based on FIG. 5). Areas in which the wires W are aligned by the aligning device 50 may be areas shown by dotted lines in FIG. 5.

The aligning device 30 may primarily move downward to a position spaced a predetermined height from an upper surface of the solar cell C to align the plurality of wires W downward. Then, the aligning device 30 may secondarily move downward so that a lower end comes into contact with the upper surface of the solar cell C, and then may align the plurality of wires W in a width direction so that the plurality of wires W are placed in the first printing area PA row in the longitudinal direction among the plurality of printing areas PA.

The aligning device 30 may primarily move downward from a first position P1 corresponding to the first printing area PA row and then may move a predetermined distance rearward. Then, the aligning device 30 may secondarily move downward from a second position P2 and press the plurality of wires W to the upper surface of the solar cell C to align the plurality of wires W in the width direction.

The aligning device 30 may include a base 31, a driving member 33, a slider 35, a first aligning plate 37, and a second aligning plate 39.

The base 31 may be connected to one side of the aligning device 30 and may support another configuration of the aligning device 30. For example, as illustrated in FIG. 6, the base 31 may include two bases 31, the driving member 33 may be connected to one side of the bases 31, and a pair of sliders 35 may be connected to the bottom of the bases 31. Alternatively, the base 31 may consist of a single member.

The driving member 33 may be connected to a rear surface of the base 31, may receive a control signal from the controller 90, and may move the slider 35. For example, the driving member 33 may consist of a pair of motors, and the pair of motors may move the pair of sliders 35 in the width direction (for example, the Y-axis direction of FIG. 6).

The first aligning plate 37 may be connected to a lower end of one slider 35 and may move in one direction along the slider 35. For example, the first aligning plate 37 may include a plurality of first aligning protrusions 371 on a bottom surface thereof. For example, as illustrated in FIG. 7, the plurality of first aligning protrusions 371 may extend downward from the bottom surface of the first aligning plate 37 and may be spaced from one another. The first aligning protrusions 371 may be equal in number to the plurality of wires W attached to one solar cell C. A total of twelve first aligning protrusions 371 may be provided.

The second aligning plate 39 may be connected to a lower end of the other slider 35 and may move in a second direction intersecting the first direction (for example, the Y-axis direction of FIG. 6) along the slider 35. The second aligning plate 39 may be connected to the bottom of the first aligning plate 37. In addition, the second aligning plate 39 may include a plurality of aligning grooves 391 and a plurality of second aligning protrusions 393 on a bottom surface thereof. The aligning grooves 391 are grooves formed in the bottom surface of the second aligning plate 39 in the width direction (for example, the Y-axis direction of FIG. 7) and may partition spaces for aligning the wires W together with the first aligning protrusions 371. For example, as illustrated in FIG. 8, the aligning groove 391 may be formed in either side of one second aligning protrusion 393, and an aligning space marked with a red dotted line may be partitioned between one aligning groove 391 and the first aligning protrusion 371. In addition, the aligning groove 391 may be formed between two adjacent second aligning protrusions 393. The aligning grooves 391 and the second aligning protrusions 393 may be equal in number to the first aligning protrusions 371.

With such a configuration, the first aligning plate 37 and/or the second aligning plate 39 may, while moving leftward or rightward, narrow the width of the aligning groove 391 between the first aligning protrusion 371 and the second aligning protrusion 393 and move the wire W in the width direction to align the wire W to the printing area PA.

For example, as illustrated in FIG. 9, the printing area PA has a length L1 in the width direction, and the aligning groove 391 has a length L2 in the width direction. For example, L2 may be longer than L1, and L2 may be greater than or equal to 1.3 times L1 but less than or equal to 2 times L1. If L2 is less than 1.3 times L1, the width of the aligning groove 391 may be too narrow and the wire W may deviate from the aligning groove 391, and if L2 exceeds 2 times L1, the size of the aligning device 30 may be too large and may interfere with a printing area PA adjacent thereto. For example, L2 may be greater than or equal to 1.4 times L1 but less than or equal to 1.8 times L1.

A depth L3 of the aligning groove 391 may be less than a diameter D of the wire W. Accordingly, in a state in which the aligning device 30 is in contact with the upper surface of the solar cell C, that is, in a state in which the aligning device 30 has secondarily moved downward, the wire W may be pressed downward by the aligning groove 391, and the position of the wire W may be aligned more reliably. Embodiments relating to an operation of the aligning device 30 will be described in detail with reference to FIGS. 9 to 16.

After wires W are cut and a new good solar cell GC is seated on the stage 10, the aligning device 30 may move to an aligning position. For example, the aligning device 30 may be located at a first position P1 corresponding to a first printing area PA row of the new good solar cell GC or a third position P3 corresponding to a first printing area PA row of a good solar cell GC adjacent thereto (see FIGS. 2G and 2I). For convenience of description, an operation in which the aligning device 30 aligns wires W at the first position P1 corresponding to the first printing area PA row of the new good solar cell GC will be described below. Here, one of two wires W may be attached to a printing area PA of a solar cell C, and the other wire W may be deviated from the printing area PA in the width direction and height direction. In this state, the aligning device 30 may be located so that a center of the aligning groove 391 is misaligned with a center of the printing area PA. For example, as illustrated in FIG. 9, the aligning device 30 may be located so that the center of the aligning groove 391 in the width direction is closer to the wire W deviated from the printing area PA.

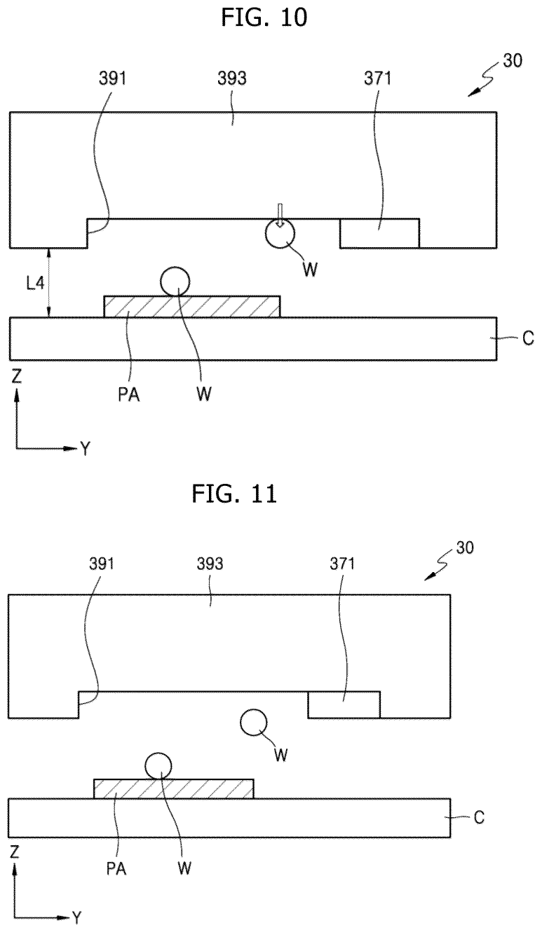

Next, the aligning device 30 primarily moves downward (see FIG. 10). As the aligning device 30 moves downward, the wire W deviated from the printing area PA comes into contact with the aligning groove 391 and also moves downward. At the time of primary downward movement, the aligning device 30 may be spaced from an upper surface of the solar cell C. That is, at the time of primary downward movement, the aligning device 30 may not press the wire W, and the wire W may not come into contact with the printing area PA. If the aligning device 30 moves downward and comes into contact with the upper surface of the solar cell C at the time of primary downward movement, since solder applied on the printing area PA may come into contact with the wire W, the wire W may not be aligned properly in an aligning operation at the time of secondary downward movement afterwards. At the time of primary downward movement, the aligning device 30 aligning the wire W deviated from the printing area PA downward is sufficient. As illustrated in FIG. 10, the aligning device 30 may primarily move downward until a lower end of the aligning device 30 is spaced a length L4 from the upper surface of the solar cell C. Also, L4 may be greater than a diameter of the wire W so that the wire W is not pressed at the time of primary downward movement. That is, the aligning device 30 may press the wire W until the lower end of the aligning device 30 is spaced the length L4 from the upper surface of the solar cell C, and as a result, the degree to which the wire W is lifted, for example, the degree to which a tip area of the wire W is lifted, in a third direction (for example, the Z-axis direction of FIG. 10 or the height direction) may be reduced. Accordingly, the aligning device 30 may effectively control the positions of the wires W in a string repair process that is performed afterwards.

Next, the aligning device 30 moves upward (see FIG. 11) and moves rearward to move to a position corresponding to the second position P2 (see FIG. 2H). Here, as illustrated in FIG. 15, the second position P2 may be a position at which the aligning device 30, which has moved downward, can fuse the wires W in the first printing area PA row. The second position P2 may be a position spaced rearward from the first printing area PA row.

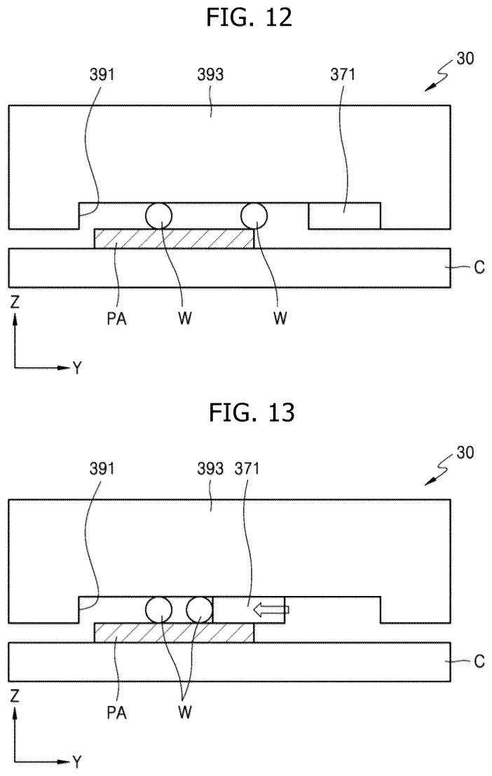

At the second position P2, the aligning device 30 secondarily moves downward (see FIG. 12). At the time of secondary downward movement, the aligning device 30 moves downward so that an upper surface of the aligning groove 391 comes into contact with the wires W. Since a depth of the aligning groove 391 is smaller than the diameter of the wires W, the wires W may have a somewhat dented shape due to being pressed on the upper surface of the solar cell C. Although the aligning device 30 is illustrated as spaced from the upper surface of the solar cell C in FIG. 12, the aligning device 30 may be in contact with the upper surface of the solar cell C while portions of the first aligning plate 37 and the second aligning plate 39 are spaced from the upper surface of the solar cell C only in the vicinity of the printing area PA where alignment is performed. That is, at the second position P2, the aligning device 30 may be supported by the upper surface of the solar cell C. Alternatively, at the second position P2, the aligning device 30 may remain spaced from the upper surface of the solar cell C.

Next, the aligning device 30 aligns the wires W in the width direction (see FIG. 13). For example, as the driving member 33 operates and the sliders 35 move, the first aligning plate 37 moves toward the wires W. The first aligning plate 37 may push the wire W deviated from the printing area PA and move the wire W into the printing area PA. For example, the first aligning plate 37 may align the two wires W so that the wires W do not come into contact with each other. If the two wires W come into contact with each other, in some cases, the solar cell C may be damaged when the two wires W are laminated in the height direction and then sealed to the string S by a laminator. In order to prevent this, the first aligning plate 37 may push the wire W inward past an edge of the printing area PA and align the wire W to be spaced from the wire W attached to the printing area PA. Although it is shown in the drawing that the first aligning plate 37 moves while the aligning device 30 is spaced from the upper surface of the solar cell C, the first aligning plate 37 may move while a portion of the aligning device 30 not illustrated in the drawing is in contact with and supported by the upper surface of the solar cell C.

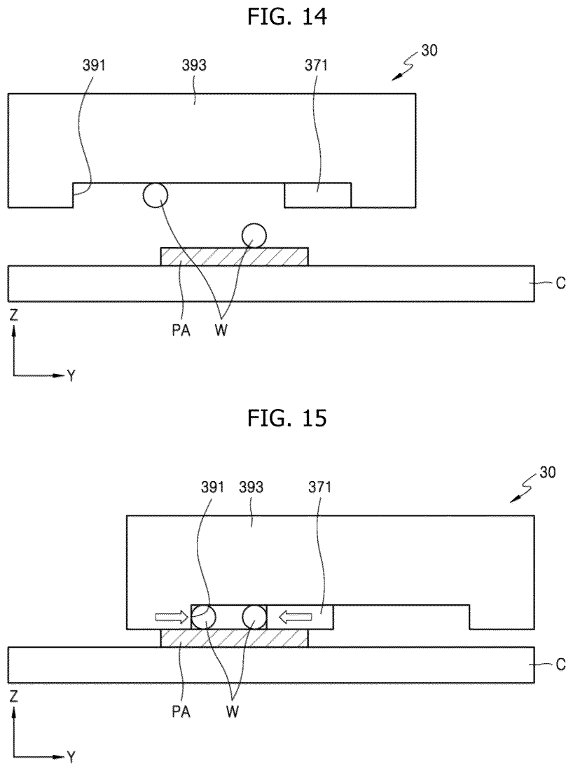

Alternatively, both the first aligning plate 37 and the second aligning plate 39 may move and align the wires W. As illustrated in FIG. 14, in a state in which the wire W is deviated toward a left side of the printing area PA, the center of the aligning groove 391 of the aligning device 30 may be located more leftward than the center of the printing area PA. That is, depending on the position of the wire W deviated from the printing area PA, the center of the aligning groove 391 of the aligning device 30 may be located to be spaced leftward from the center of the printing area PA or may be located to be spaced rightward therefrom.

In this state, as in the above-described embodiment, the aligning device 30 primarily moves downward to align the wires W in the height direction, moves upward, moves to the second position P2, and then secondarily moves downward. After secondarily moving downward, the aligning device 30 may move both the first aligning plate 37 and the second aligning plate 39 to align the wires W. As illustrated in FIG. 15, the first aligning protrusion 371 moves leftward in a state in which the upper surface of the aligning groove 391 is in contact with the wires W. At this time, the first aligning protrusion 371 moving to come into contact with the wire W attached to the printing area PA is sufficient. Then, as the second aligning protrusion 393 moves rightward, the aligning groove 391 between the first aligning protrusion 371 and the second aligning protrusion 393 narrows. The second aligning protrusion 393 may press the wire W and push the wire W into the printing area PA. Although it is shown in the drawing that the first aligning protrusion 371 and the second aligning protrusion 393 move while the aligning device 30 is spaced from the upper surface of the solar cell C, the first aligning protrusion 371 and the second aligning protrusion 393 may move while a portion of the aligning device 30 not illustrated in the drawing is in contact with and supported by the upper surface of the solar cell C.

In this way, the first aligning plate 37 and/or the second aligning plate 39 of the aligning device 30 may move to align the wire W deviated from the printing area PA so that the wire W enters the printing area PA. Accordingly, the new solar cell C may be connected well to another solar cell C.

The aligning device 30 may overlap with a portion of the bonding device 50 when the bonding device 50 bonds the wire W. For example, as illustrated in FIG. 16, in a state in which the wire W is aligned by the aligning device 30 secondarily moving downward, a lower end of a heating part 51 of the bonding device 50 may be supported on the first aligning plate 37 and the second aligning plate 39 of the aligning device 30. Accordingly, by placing the first aligning plate 37 and the second aligning plate 39 as close as possible to the position where the bonding device 50 fuses the wire W, the aligning device 30 can reliably support and align the wire W even during a fusion process.

The separating device 40 may remove a wire W attached to a solar cell C. For example, the separating device 40 may be mounted on the first moving head 23 and may be used in removing a solar cell C attached to a defective solar cell NC. For example, as illustrated in FIG. 2B, in a state in which the stages 10 supporting good solar cells C at both sides of a defective solar cell NC have moved upward and downward, based on the defective solar cell NC, the separating device 40 may move to an upper portion of the defective solar cell NC. Here, the separating device 40 may be adjacent to an end of the defective solar cell NC (for example, a left end thereof in FIG. 2B). For example, the separating device 40 may be located to correspond to a wire W attached to a printing area PA closest to one end of the defective solar cell NC. As illustrated in FIG. 3, the separating device 40 may allow a wire W, which extends from a good solar cell C at one side, to be separated on an upper surface of a defective solar cell NC at a position closest to an end of the defective solar cell NC (for example, a left end in FIG. 3) and slightly farther from an end of a first printing area PA row (for example, a right end in FIG. 3). Accordingly, the length of the wire W of the good solar cell GC can be sufficiently secured, and the wire W can be stably bonded to the first printing area PA row of the new good solar cell GC.

The separating device 40 may be a hot air blower. The separating device 40 may separate a wire W from a solar cell C by melting solder between the wire W and the solar cell C by spraying high-temperature air or a gas satisfying a predetermined atmosphere onto the wire W.

The separating device 40 may be equal in number to a plurality of wires W attached to a single solar cell C. The separating devices 40 may simultaneously spray hot air to twelve wires W through twelve outlets. Alternatively, the separating device 40 may be fewer in number than a plurality of wires W attached to a single solar cell C. The separating devices 40 may spray hot air to six wires W through six outlets, move, and then spray hot air to the remaining six wires W.

The bonding device 50 may bond a wire W aligned by the aligning device 30 to a new good solar cell GC. For example, as illustrated in FIG. 2H, after a defective solar cell NC is replaced with a good solar cell GC, a wire W extending from an adjacent good solar cell GC may be aligned by the aligning device 30. Also, the bonding device 50 may bond the wire W to an upper surface of the new good solar cell GC. Here, at least a portion of the bonding device 50 may overlap with a printing area PA closest to an end of the new good solar cell GC (for example, a left end thereof in FIG. 2H). In addition, as illustrated in FIG. 2J, a wire W extending from the new good solar cell GC may be aligned by the aligning device 30 on an upper surface of another good solar cell GC. Also, the bonding device 50 may bond the wire W to the upper surface of the good solar cell GC. Here, at least a portion of the bonding device 50 may overlap with a printing area PA closest to an end of the other good solar cell GC (for example, a left end thereof in FIG. 2J).

The bonding device 50 may be a high-frequency fusion bonding device. The bonding device 50 may melt solder applied to the wire W of the new good solar cell GC and bond the wire W to the printing area PA.

A portion of the bonding device 50 may be supported by the aligning device 30 in a bonding process. For example, as illustrated in FIG. 16, the bonding device 50 may include the heating part 51 and a pressing part 53, and a lower end of the pressing part 53 may be supported by the first aligning plate 37 and the second aligning plate 39 of the aligning device 30. In this state, the pressing part 53 may come into contact with the wire W. Accordingly, a position at which the bonding device 50 comes into contact with the wire W may be stably maintained by the aligning device 30.

For example, the bonding device 50 may be equal in number to a plurality of wires W attached to a single solar cell C. The bonding devices 50 may simultaneously bond twelve wires W to the solar cell C through the pressing parts 53. Alternatively, the bonding device 50 may be fewer in number than a plurality of wires W attached to a single solar cell C. The bonding devices 50 may bond six wires W to the solar cell C through six pressing parts 53, move, and then bond the remaining six wires W to the solar cell C.

The robot arm 60 is present on one side of the stage 10 and performs an inspecting operation, a cutting operation, a bonding operation, and so on. For example, the robot arm 60 is a six-axis robot including a vision camera 61, a single cutter 63, a single bonding device 65, and the cutter 67. As illustrated in FIG. 1, the vision camera 61, the single cutter 63, the single bonding device 65, and the cutter 67 may be arranged clockwise or counterclockwise, and the robot arm 60 may rotate at 90° intervals and place the components at process positions on the string S.

The vision camera 61 may, after an end of each process of string repair, inspect whether the corresponding process has been performed properly. For example, the vision camera 61 may, after a process of cutting a wire W by the cutter 67, check a cut surface of the wire W and determine whether the wire W has been cut properly. Also, the vision camera 61 may check whether the wire W has been attached properly to a solar cell C by the bonding device 50. In addition, the vision camera 61 may be used to check another process of string repair as necessary. For example, the vision camera 61 may inspect whether the string S has been mounted properly on the stage 10, whether the wire W has been separated properly by the separating device 40, or whether a defective solar cell NC has been discharged and a new good solar cell GC has been mounted.

The single cutter 63 and the cutter 67 may cut a wire W. For example, after a wire W is separated by the separating device 40, as illustrated in FIG. 2C, the cutter 67 may cut the separated wire W on an upper surface of a defective solar cell NC. The cutter 67 may be equal in number to a plurality of wires W attached to a single solar cell C. Alternatively, the cutter 67 may be fewer in number than a plurality of wires W attached to a single solar cell C. For example, the number of blades of the cutter 67 may be four, and the cutter 67 may cut twelve wires W through three cutting operations.

Also, as illustrated in FIG. 2C, after cutting the separated wire W on the upper surface of the defective solar cell NC, the cutter 67 may move to a good solar cell GC to which the wire W of the defective solar cell NC extends. The cutter 67 may cut the wire W at one end of the good solar cell GC.

The single cutter 63 may perform an additional cutting operation when, after the cutting operation by the cutter 67 is completed, the vision camera 61 checks the cut surface of the wire W and then determines that cutting has not been performed properly. For example, the single cutter 63 may have a blade to be able to cut a single wire W. When the vision camera 61 detects a wire W that has not been cut properly among a plurality of wires W, the single cutter 63 may move to the corresponding wire W and perform a cutting operation for each wire again.

The single bonding device 65 may perform an additional bonding operation when, after the bonding operation by the bonding device 50 is completed, the vision camera 61 checks a bonding position of a wire W and then determines that bonding has not been performed properly. For example, the single bonding device 65 may be a high-frequency fusion bonding device that can bond a single wire W to a solar cell C. When the vision camera 61 detects a wire W that has not been bonded properly among a plurality of wires W, the single bonding device 65 may move to the corresponding wire W and perform a bonding operation for each wire again.

The transporting device 70 may transport a string S placed outside the string repair device 1 to the inside thereof or may transport a string S within the string repair device 1. For example, the transporting device 70 may transport a string S determined to be defective by the inspecting device 3 to a stage 10 and may transport the stage 10 on which repair of the string S has been completed to the outside of the string repair device 1. Also, the transporting device 70 may transport the stage 10 on which repair of the string S has been completed back to the inspecting device 3 for the inspecting device 3 to inspect whether the string S has been repaired properly.

The magazine 80 may contain a plurality of good solar cells GC. When a stage 10 discharges a defective solar cell NC, the third moving head 29 may, while supporting the good solar cells GC loaded in the magazine 80, move along the third horizontal guide 27 to a position where the discharged defective solar cell NC was present. Also, the third moving head 29 may place the good solar cells GC supported thereby on a stage 10 at the corresponding position.

The controller 90 may be connected to other components of the string repair device 1 wirelessly or via a wire and may control these components. For example, the controller 90 may control lifting/lowering and forward/backward movements of a stage 10. Also, the controller 90 may control positions of the aligning device 30, the separating device 40, and the bonding device 50 by controlling the movement guide 20 and may control an operation of each of the aligning device 30, the separating device 40, and the bonding device 50. In addition, the controller 90 may control the robot arm 60 to control operations of the vision camera 61, the single cutter 63, the single bonding device 65, and the cutter 67.

The controller 90 may use a direct circuit structure that executes each control function through one or more microprocessors or other control devices, such as a memory, a processor, a logic circuit, or a look-up table. The controller 90 may be implemented as a module, a program, or part of a code that includes one or more executable instructions for executing a specific logic function. The controller 90 may include, or may be implemented by, a processor such as a central processing unit executing each function or microprocessor. The controller 90 may include a communication device that can transmit and receive data to and from an external device or the like. The communication device may include a digital modem, a radiofrequency (RF) modem, an antenna circuit, a Wi-Fi chip, related software and/or firmware, or a combination of one or more thereof.

Next, operations of the string repair device 1 and a string repair method will be described.

A string repair method includes placing a string S including a plurality of solar cells C and a plurality of wires W connecting the plurality of solar cells C on a stage 10, cutting a plurality of wires W connected between a defective solar cell NC and two solar cells GC adjacent to the defective solar cell NC among the plurality of solar cells C, replacing the defective solar cell NC with a new solar cell GC, and aligning a plurality of wires W attached to the new solar cell GC and a plurality of wires W of the solar cells GC adjacent to the new solar cell GC, wherein the plurality of solar cells GC include a plurality of printing areas PA to which the plurality of wires W are attached, and the aligning of the plurality of wires W includes maintaining the plurality of wires W attached to the new solar cell GC and the plurality of wires W of the two solar cells GC adjacent to the new solar cell GC in the plurality of printing areas PA.

The aligning of the plurality of wires W may include aligning the plurality of wires W downward at positions corresponding to a first printing area PA row of the solar cells C, pressing the plurality of wires W toward upper surfaces of the solar cells C at positions spaced rearward from the positions corresponding to the first printing area PA row of the solar cells C, and aligning the plurality of wires W to the first printing area PA row by pressing the plurality of wires W in the width direction.

The aligning of the plurality of wires W may include, after performing a series of aligning steps for a plurality of wires W of a new solar cell C, performing the series of aligning steps for a plurality of wires W of a solar cell C adjacent to the new solar cell C.

First, when the inspecting device 3 determines that a string S is defective, the controller 90 sends a signal to the transporting device 70, and the transporting device 70 mounts the corresponding string S on a stage 10 (see FIG. 2A). The transporting device 70 transports the string S so that a defective solar cell NC included in the string S is placed on a central portion of the stage 10 and the remaining good solar cells GC are placed on other portions of the stage 10.

Next, the controller 90 sends a lifting/lowering signal to the stage 10 and moves the separating device 40 to the defective solar cell NC (see FIG. 2B). Based on the stage 10 on which the defective solar cell NC is mounted, the stage 10 located at a front moves upward and the stage 10 located at a rear moves downward, thereby forming step differences between the good solar cells GC and the defective solar cell NC. Then, while located to correspond to the first printing area PA row of the defective solar cell NC, the separating device 40 separates a wire W from the defective solar cell NC by heating the wire W. Then, the controller 90 sends a cutting signal to the robot arm 60, and the robot arm 60 moves to a position where the wire W has been separated and cuts the wire W with the cutter 67. As illustrated in FIG. 3, the cutter 67 may cut the wire W so that the wire W extends rearward past the first printing area PA row of the defective solar cell NC. Also, as illustrated in FIG. 3, the cutter 67 cuts the wire W extending from the defective solar cell NC at a front end of the good solar cell GC located at the rear of the defective solar cell NC (see FIGS. 2C and 2D). The cutter 67 may cut the wires W in reverse order, or a plurality of cutters 67 may simultaneously cut each wire W.

Whether cutting has been performed properly by the cutter 67 may be checked through the vision camera 61. For example, after the cutting operation by the cutter 67, the controller 90 sends an inspection signal to the robot arm 60, and the robot arm 60 checks a cut surface of the wire W using the vision camera 61. If the wire W has been cut properly, the controller 90 performs a subsequent process. If the wire W has not been cut properly, the robot arm 60 uses the single cutter 63 to individually cut the wire W that has not been cut properly.

Then, the controller 90 sends a discharge signal to the stage 10, and the stage 10 supporting the defective solar cell NC rotates and discharges the defective solar cell NC (see FIG. 2E). Accordingly, as illustrated in FIG. 4, the stage 10 on which the discharged defective solar cell NC was present becomes unoccupied. Next, the controller 90 sends a lifting/lowering signal to the stage 10 and sends a pickup signal to the magazine 80 or the third moving head 29. The stages 10 located at both sides of the unoccupied stage 10 move downward and upward and return to their original positions, and the third moving head 29 supports a new good solar cell GC and mounts the new good solar cell GC on the unoccupied stage 10 (see FIG. 2F).

Next, the controller 90 sends an alignment signal to the aligning device 30. The aligning device 30 moves to a position corresponding to the first printing area PA row of the defective solar cell NC, that is, the first position P1, and then primarily moves downward (see FIG. 2G). Accordingly, the wire W extending from the good solar cell GC located at the front and stretching to an upper portion of the new good solar cell GC is aligned downward. Then, the aligning device 30 moves upward again, moves rearward, moves to the second position P2, and then secondarily moves downward. The aligning device 30 that has secondarily moved downward gathers the wire W in the width direction while pressing the wire W downward and places the wire W extending from the good solar cell GC located at the front in the first printing area PA row. Then, the bonding device 50 receives a signal from the controller 90, moves to the first position P1, and then moves downward. The bonding device 50 bonds two wires W located in a single first printing area PA row, that is, the wire W extending from the good solar cell GC located at the front and the wire W attached to the new good solar cell GC, in the first printing area PA row (see FIG. 2H).

Then, the aligning device 30 moves rearward again, moves to a position corresponding to the first printing area PA row of the good solar cell GC located at the rear, that is, the third position P3, and then primarily moves downward (see FIG. 2I). Accordingly, the wire W extending from the new good solar cell GC and stretching to an upper portion of the good solar cell GC located at the rear is aligned downward. Then, the aligning device 30 moves upward again, moves rearward, moves to a fourth position P4, and then secondarily moves downward. The aligning device 30 that has secondarily moved downward gathers the wire W in the width direction while pressing the wire W downward and places the wire W extending from the new good solar cell GC in the first printing area PA row. Then, the bonding device 50 receives a signal from the controller 90, moves to the third position P3, and then moves downward. The bonding device 50 bonds two wires W located in a single first printing area PA row, that is, the wire W extending from the new good solar cell GC and the wire W attached to the good solar cell GC located at the rear, in the first printing area PA row (see FIG. 2J).

As illustrated in FIG. 5, the wires W are bonded in the first printing area PA row of the new good solar cell GC and the first printing area PA row of the good solar cell GC located at the rear. Accordingly, the plurality of solar cells C included in the string S are all electrically connected by the wires W.

Whether bonding has been performed properly may be checked using the vision camera 61. For example, after the bonding operation by the bonding device 50, the controller 90 sends an inspection signal to the robot arm 60, and the robot arm 60 checks states of the bonded wires W in the printing areas PA using the vision camera 61. If the wires W are bonded properly in the printing areas PA, the controller 90 performs a subsequent process. If the wires W are not bonded properly in the printing areas PA, the robot arm 60 uses the single bonding device 65 to individually bond the wire W that has not been bonded properly.

Although the present invention has been described above with reference to the embodiments illustrated in the drawings, the description is merely illustrative. Those of ordinary skill in the art may fully understand that various modifications and other equivalent embodiments are possible from the embodiments. Therefore, the true technical protection scope of the present invention should be defined based on the appended claims.

### INDUSTRIAL APPLICABILITY

Embodiments of the present disclosure may be used in industries relating to a string repair device and a string repair method.

1. A string repair device comprising:
a stage supporting a string including a plurality of solar cells and a plurality of wires connecting the plurality of solar cells; and
an aligning device configured to, after a defective solar cell of the string is replaced with a new solar cell, align a plurality of wires attached to the new solar cell and a plurality of wires of two solar cells adjacent to the new solar cell,
wherein the plurality of solar cells include a plurality of printing areas to which the plurality of wires are each attached, and
the aligning device aligns the plurality of wires attached to the new solar cell and the plurality of wires of the two solar cells adjacent to the new solar cell in the plurality of printing areas.

2. The string repair device of claim 1, wherein:
the plurality of printing areas form a plurality of rows in a longitudinal direction; and
the aligning device aligns a plurality of wires of a solar cell adjacent to a front of the new solar cell so that the plurality of wires are located in a first printing area row of the new solar cell and aligns the plurality of wires attached to the new solar cell so that the plurality of wires are located in a first printing area row of a solar cell adjacent to a rear of the new solar cell.

3. The string repair device of claim 1, wherein the aligning device primarily moves downward to a position spaced a predetermined height from an upper surface of the solar cell to align the plurality of wires downward, secondarily moves downward so that a lower end comes into contact with the upper surface of the solar cell, and then aligns the plurality of wires in a width direction.

4. The string repair device of claim 3, wherein:
the plurality of printing areas form a plurality of rows in a longitudinal direction; and
the aligning device primarily moves downward from a first position corresponding to a first printing area row, secondarily moves downward from a second position reached by moving a predetermined distance rearward, presses the plurality of wires to the upper surface of the solar cell, and then aligns the plurality of wires in a width direction.

5. The string repair device of claim 3, further comprising a bonding device bonding the plurality of wires aligned by the aligning device to the solar cell,
wherein the bonding device is supported on the aligning device so that at least a portion overlaps the aligning device in a state in which the aligning device is secondarily moved downward.

6. The string repair device of claim 1, wherein the aligning device includes:
a first aligning plate including a plurality of first aligning protrusions; and
a second aligning plate including a plurality of aligning grooves and a plurality of second aligning protrusions arranged alternately with the plurality of first aligning protrusions,
wherein the aligning device moves at least one of the first aligning plate and the second aligning plate to align the plurality of wires, which are inserted into the plurality of aligning grooves, in a width direction.

7. The string repair device of claim 6, wherein:
a depth of the plurality of aligning grooves is smaller than a diameter of the wires; and
a width of the plurality of aligning grooves is greater than a width of the printing areas.

8. A string repair method comprising:
placing a string including a plurality of solar cells and a plurality of wires connecting the plurality of solar cells on a stage;
cutting a plurality of wires connected between a defective solar cell and two solar cells adjacent to the defective solar cell among the plurality of solar cells;
replacing the defective solar cell with a new solar cell; and
aligning a plurality of wires attached to the new solar cell and a plurality of wires of the solar cells adjacent to the new solar cell,
wherein the plurality of solar cells include a plurality of printing areas to which the plurality of wires are attached, and
the aligning of the plurality of wires includes aligning the plurality of wires attached to the new solar cell and the plurality of wires of the two solar cells adjacent to the new solar cell in the plurality of printing areas.

9. The string repair method of claim 8, wherein:
the plurality of printing areas form a plurality of rows in a longitudinal direction; and
the aligning of the plurality of wires includes aligning the plurality of wires downward from a position corresponding to a first printing area row of the solar cell, pressing the plurality of wires to an upper surface of the solar cell from a position spaced rearward from the position corresponding to the first printing area row, and aligning the plurality of wires in the first printing area row by pressing the plurality of wires in a width direction.

10. The string repair method of claim 9, wherein the aligning of the plurality of wires includes, after performing a series of aligning steps for a plurality of wires of the new solar cell, performing the series of aligning steps for a plurality of wires of a solar cell adjacent to a rear of the new solar cell.
